(19) United States
(12) Patent Application Publication
(10) Pub. No.: US 2016/0049524 A1
(43) Pub. Date: Feb. 18, 2016

(54) DISPLAY PANEL

(71) Applicant: InnoLux Corporation, Miao-Li County (TW)

(72) Inventors: I-Ho SHEN, Miao-Li County (TW); Geeng-Jieh CHONG, Miao-Li County (TW)

(21) Appl. No.: 14/793,792

(22) Filed: Jul. 8, 2015

(30) Foreign Application Priority Data
Aug. 12, 2014 (TW) 103127623

(51) Int. Cl. H01L 29/786; H01L 27/12; H01L 29/06

(52) U.S. Cl. CPC H01L 29/78696; H01L 29/7869; H01L 29/0649; H01L 27/1225; H01L 27/1248; H01L 29/78633

(57) ABSTRACT

A display panel is disclosed, which comprises: a substrate; a thin film transistor unit disposed on the substrate, wherein the thin film transistor unit comprises a gate electrode and a semiconductor layer, wherein the semiconductor layer comprises a carrier channel region, and the gate electrode is disposed corresponding to the carrier channel region; a first metal oxide layer disposed on the semiconductor layer and covering the carrier channel region; and an isolation layer containing silicon oxide (SiOx) or aluminum oxide (Al₂O₃) disposed between the semiconductor layer and the first metal oxide layer; wherein the light transmittance of light with wavelength range from 210 nm to 350 nm through the first metal oxide layer is under or equal to 50%

### CROSS REFERENCE TO RELATED APPLICATION

This application claims the benefits of the Taiwan Patent Application Serial Number 103127623, filed on Aug. 12, 2014, the subject matter of which is incorporated herein by reference.

### BACKGROUND OF THE INVENTION

1. Field of the Invention

The present invention relates to a display panel, and especially to a display panel with a thin film transistor unit having an improved actuating stability.

2. Description of Related Art

As the development of display technology advances, users now have higher requirements for electronic products. All the devices are now developed toward small, thin, light weight, and so on. Therefore, the mainstream display devices on the market have evolved from the cathode ray tubes to the liquid crystal display device (LCD) or the organic light-emitting diode device (OLED).

In LCD or OLED, since the band gap of the active layer material of a thin film transistor unit (TFT) is similar to that of ultraviolet (UV) light and blue light, TFT is, thus, very sensitive to ultraviolet light and blue light. Under the ultraviolet light or blue light irradiation (for example, the ultraviolet light or blue light irradiation during the manufacturing process or from the external environment), TFT will generate additional electron-hole pairs. This will cause the channel of TFT to have additional carriers. Consequently, this will result in the electrical offsets of TFT such as gate voltage (Vth) negative bias, increased leakage current, and so on. Moreover, this will also result in the light leakage of OLED during the dark-state operation. Malfunctions of shift register (S/R), data multiplexer (Data Mux), and other drive circuits will also occur.

Hence, there is an urgent need to develop a display panel capable of solving the above-mentioned problems. Such display panel can enhance better display quality and extend its service life. This display panel will also provide more stable display performance and higher display quality.

### SUMMARY OF THE INVENTION

An object of the present invention is to provide a display panel capable of reducing the sensitivity of the thin film transistor unit in the display device from UV or blue light, thereby effectively enhancing the stability and display quality of the display device.

In order to achieve the above object, the present invention provides a display panel comprising: a substrate; a thin film transistor unit disposed on the substrate, wherein the thin film transistor unit comprises a gate electrode and a semiconductor layer, wherein the semiconductor layer comprises a carrier channel region, and the gate electrode is disposed corresponding to the carrier channel region; a first metal oxide layer disposed on the semiconductor layer and covered the carrier channel region; and an isolation layer containing silicon oxide (SiOx) or aluminum oxide (Al₂O₃) disposed between the semiconductor layer and the first metal oxide layer; wherein the light transmittance of light with wavelength range from 210 nm to 350 nm through the first metal oxide layer is under or equal to 50%.

The present invention hereby uses the first metal oxide layer to absorb lights with short wavelengths (for example, the ultraviolet light or blue light irradiation during the manufacturing process or from the external environment). This will effectively decrease the probability of the lights with short wavelengths be emitted into the semiconductor layer of the thin film transistor unit. The electrical characteristics shift of the thin film transistor unit will be reduced. The light leakage of OLED during the dark-state operation will be improved. Other problems such as the malfunctions of shift register (S/R), data multiplexer (Data Mux), and other drive circuits will also be improved. Therefore, this invention can provide more stable display performance and higher display quality.

### BRIEF DESCRIPTION OF THE DRAWINGS

FIG. 1 shows a schematic diagram of the thin film transistor unit according to a preferred embodiment of the present invention.

FIG. 2 shows a schematic diagram of the thin film transistor unit according to another preferred embodiment of the present invention.

FIG. 3 shows a schematic diagram of the thin film transistor unit according to another preferred embodiment of the present invention.

FIG. 4A shows an exploded view of the thin film transistor unit according to a preferred embodiment of the present invention.

FIG. 4B shows a top view of the thin film transistor unit according to a preferred embodiment of the present invention.

### DETAILED DESCRIPTION OF THE PREFERRED EMBODIMENT

Hereinafter, exemplary examples of the present invention will be described in detail. However, the present invention is not limited to the examples disclosed below, but can be implemented in various forms. The following examples are described in order to enable those of ordinary skill in the art to embody and practice the present invention, and those skilled in the art will appreciate that various modifications, additions, and substitutions are possible.

### Embodiment 1

Referring to FIG. 1, the display panel according to a preferred embodiment of the present invention comprises: a substrate 1; a thin film transistor unit disposed on the substrate 1, wherein the thin film transistor unit comprises: a gate electrode 21, a semiconductor layer 22, and an insulating layer 26, wherein the semiconductor layer 22 comprises a carrier channel region 221, and the gate electrode 21 is disposed corresponding to the carrier channel region 221; a first metal oxide layer 32 disposed on the semiconductor layer 22 and covered the carrier channel region 221; and an isolation layer 31 containing silicon oxide (SiOx) or aluminum oxide (Al₂O₃) disposed between the semiconductor layer 22 and the first metal oxide layer 32; wherein the light transmittance of light with wavelength range from 210 nm to 350 nm through the first metal oxide layer 32 is under or equal to 50%.

In the present embodiment, the thin film transistor unit may further comprise a source electrode 23 and a drain electrode 24, wherein the source electrode 23 and the drain electrode 24 are disposed above and connected to the semiconductor layer 22. The first metal oxide layer 32 is disposed between the semiconductor layer 22 and both of the source electrode 23 and the drain electrode 24. However, the first metal oxide layer 32 may also be disposed above and cover the source electrode 23 and the drain electrode 24. In addition, in this embodiment, the first metal oxide layer 32 is disposed above the semiconductor layer 22 and coated on a sidewall 222 of the semiconductor layer 22. However, the first metal oxide layer 32 could only cover the carrier channel region 221. Depending on different requirements, the first metal oxide layer 32 may optionally cover the sidewall 222 of the semiconductor layer 22. If the first metal oxide layer 32 covers the sidewall 222 of the semiconductor layer 22, the electrical characteristics shift of the thin film transistor unit may be advantageously reduced and the light leakage of the display device during the dark-state operation may also be improved.

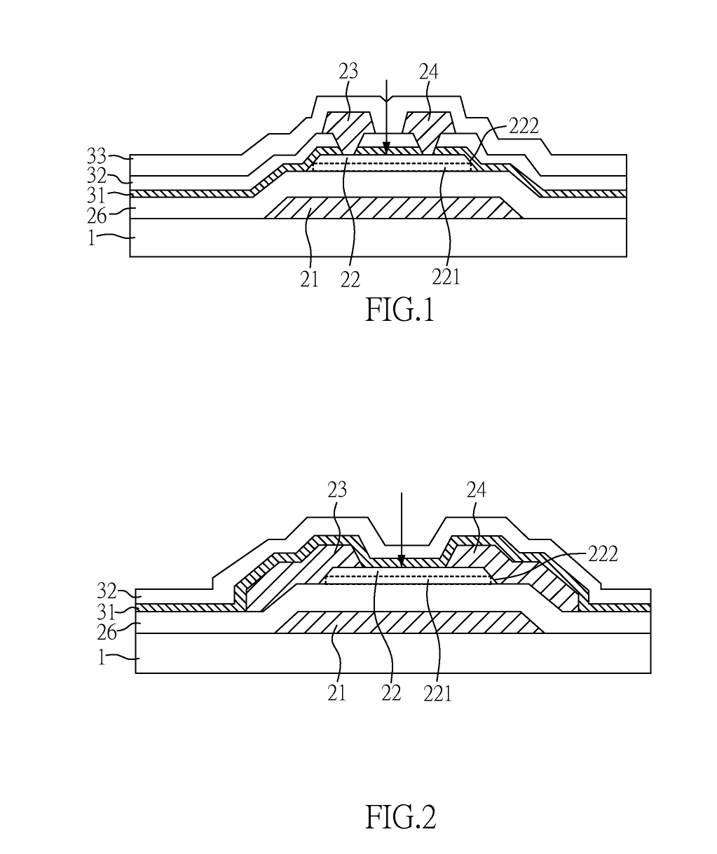

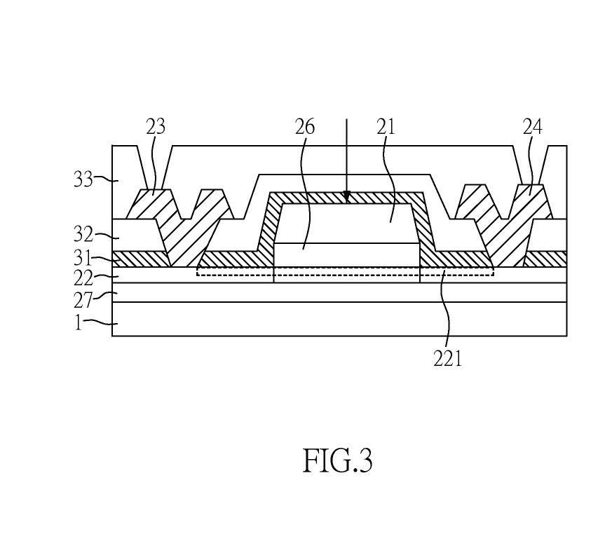

In the present embodiment, the thin film transistor unit shown in FIG. 1 is a bottom gate thin film transistor unit. The source electrode 23 and the drain electrode 24 are disposed above the semiconductor layer 22. The semiconductor layer 22 is disposed above the gate electrode 21 and serves as an etching stop layer structure (ESL). The thin film transistor unit may be prepared by any conventional process, and thus, will not be described in detail here. The thin film transistor unit structure may simply be adjusted by a person skilled in the art. It may also be a back channel etching structure (BCE) as shown in FIG. 2 or a top gate thin film transistor unit as shown in FIG. 3. It should be noted that the carrier channel region in the semiconductor layer is mainly at the position closer to the gate electrode. Hence, the positions of the carrier channel region 221 in FIGS. 1 and 2 are different from that in FIG. 3.

In the present embodiment, the material of the first metal oxide layer 32 is not limited and may be titanium oxide (TiOx), molybdenum oxide (MoOx), zinc oxide (ZnOx), indium oxide (InOx), tungsten oxide (Wax), magnesium oxide (MgOx), calcium oxide (CaOx), Stannic oxide (SnOx), gallium oxide (GaOx), indium gallium zinc oxide (IGZO), or aluminum oxide (AlOx). The thickness of the first metal oxide layer is not limited and can be adjusted by the person skilled in the art according to the actual demands. When a light with wavelength range from 210 nm to 350 nm passes through the first metal oxide layer with a thickness in the range from 10 nm to 100 nm, the light transmittance is under or equal to 50%. When a light with wavelength range from 210 nm to 350 nm passes through the first metal oxide layer with a thickness in the range from 30 nm to 100 nm, the light transmittance is under or equal to 30%. As such, the first metal oxide layer can effectively block most of the ultraviolet light to maintain the drive voltage stability of the thin film transistor unit.

In the present embodiment, if the isolation layer 31 comprises silicon oxide (SiOx) or aluminum oxide (Al₂O₃), the thickness and area of the isolation layer 31 are not limited, the thickness of the isolation layer 31 is preferably from 5 nm to 20 nm and the area of the isolation layer 31 is preferably greater than or equal to the area of the first metal oxide layer 32.

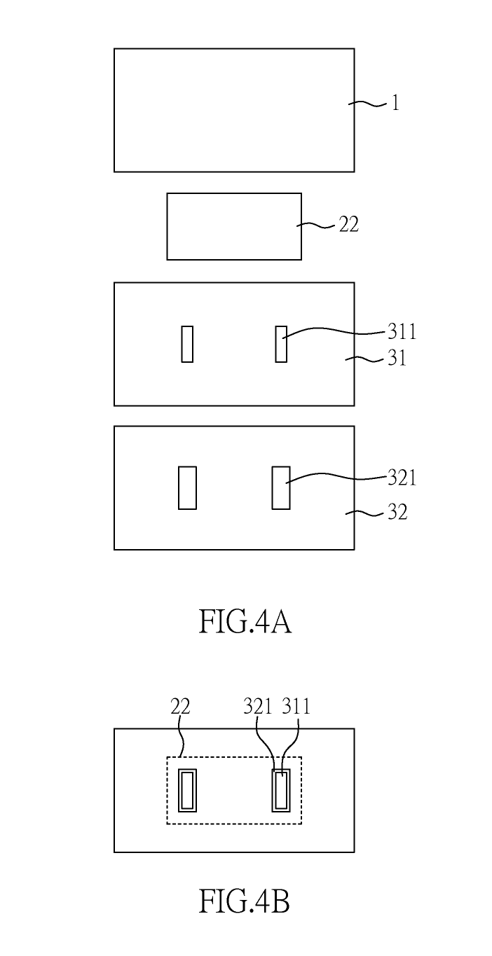

In this case, the oxygen vacancies in the semiconductor layer 22 (when the first oxide layer 32 is incompletely oxidized, the first oxide layer 32, which is in direct contact with the semiconductor layer 32, may capture the oxygen inside of the semiconductor layer 22, and cause oxygen vacancies in the semiconductor layer 22) that may affect the drive voltage stability of the thin film transistor unit can be prevented effectively. However, the present invention is not limited thereto. FIGS. 4A and 4B show an exploded view and a top view of the thin film transistor unit according to a preferred embodiment of the present invention, respectively. In order to clearly compare the areas of the isolation layer 31 and the first metal oxide layer 32, the gate electrode 21, the source electrode 23, the drain electrode 24, the second metal oxide layer 33, and the insulating layer 26 have been omitted in FIGS. 4A and 4B. As shown in FIG. 4A, the isolation layer 31 has a first contact hole 311, and the first metal oxide layer 32 has a second contact hole 321. The first contact hole 311 and the second contact hole 321 are disposed at the positions where the source electrode 23 and the drain electrode 24 disposed on. As shown in FIG. 4B, the area of the isolation layer 31 is preferably greater than the area of the first metal oxide layer 32.

In the present embodiment, the second metal oxide layer 33 may be further disposed above and cover the source electrode 23 and the drain electrode 24. This can further prevent the thin film transistor unit from being affected by UV light or blue light. The actuating stability of the display panel can therefore be enhanced. The material of the second metal oxide layer 33 is not limited and may be the same as or different from that of the first metal oxide layer 32. The material of the second metal oxide layer 33 may be selected by the person skilled in the art according to the actual demands.

In the present embodiment, the substrate 1 may be a substrate commonly used in the art, such as a glass substrate, a plastic substrate, a silicon substrate, and a ceramic substrate, etc. The gate electrode 21, the source electrode 23, and the drain electrode 24 may be made by typical conductive materials in the art, such as metal, alloy, metal oxide, metal oxynitride, or other common electrode materials in the art. However, it is preferred that the gate electrode 21, the source electrode 23, and the drain electrode 24 are made by metal. Nevertheless, the present invention is not limited thereto. The semiconductor layer 22 may also be made by typical semiconductor materials in the art, such as indium gallium zinc oxide (IGZO), indium tin zinc oxide (ITZO), other metal oxide semiconductors, amorphous silicon, polycrystalline silicon, crystalline silicon, etc. The insulating layer 26 may be made by typical passivation materials in the art, such as silicon nitride (SiNx), silicon oxide (SiOx) or the combinations thereof. Nonetheless, the present invention is not limited thereto.

Therefore, in the present embodiment, the incident light with wavelength range from 220 nm to 350 nm (for example, the ultraviolet light or blue light irradiation during the manufacturing process or from the external environment) from the external environment (as indicated by the arrow) may be absorbed by the first metal oxide layer 32 and the second metal oxide layer 33. Thereby, the impact of these lights on the semiconductor layer 22 is reduced.

Other elements of the display panel, such as an LCD panel or an organic light emitting diode (OLED) display panel have been omitted in FIG. 1. For example, in addition to the above described substrate 1, the organic thin film transistor unit 2, the first metal oxide layer 32, and the isolation layer 31, both the LCD panel and the organic light emitting diode (OLED) display panel may further include other elements. The LCD panel may further include a liquid crystal cell, a color filter unit, and a backlight module, and so on. The organic light-emitting diode display panel may further include an organic light-emitting diode, a packaging unit, and so on. People skilled in the art may easily visualize other omitted elements. Conventional elements may be employed in the present invention.

### Embodiment 2

Referring to FIG. 2, the display panel according to another preferred embodiment of the present invention comprises: a substrate 1; a thin film transistor unit disposed above the substrate 1, wherein the thin film transistor unit comprises: a gate electrode 21, a semiconductor layer 22, a source electrode 23, a drain electrode 24, and an insulating layer 26, wherein the semiconductor layer 22 includes a carrier channel region 221 which is disposed between the source electrode 23 and the drain electrode 24, and the gate electrode 21 is disposed corresponding to the carrier channel region 221; a first metal oxide layer 32 disposed on the semiconductor layer 22, coated on a sidewall 222 of the semiconductor layer 22, and covered the source electrode 23 and the drain electrode 24; and an isolation layer 31 containing silicon oxide (SiOx) or aluminum oxide (Al₂O₃) disposed between the semiconductor layer 22 and the first metal oxide layer 32; wherein the light transmittance of light with wavelength range from 210 nm to 350 nm through the first metal oxide layer 32 is under or equal to 50%.

In the present embodiment, the first metal oxide layer 32 may also be disposed between the semiconductor layer 22 and both of the source electrode 23 and the drain electrode 24. The first metal oxide layer 32 only covers the carrier channel region 221. Depending on different requirements, the first metal oxide layer 32 may optionally cover the sidewall 222 of the semiconductor layer 22.

The present embodiment is substantially the same as Embodiment 1 except for the configuration described above. Hence, the composition, thickness, area, and characteristics of each layer in Embodiment 1 are also applicable to the counterparts herein.

Therefore, in the present embodiment, the incident light with wavelength range from 220 nm to 350 nm (for example, the ultraviolet light or blue light irradiation during the manufacturing process or from the external environment) from the external environment (as indicated by the arrow) may be absorbed by the first metal oxide layer 32. Thereby, the impact of these lights on the semiconductor layer 22 is reduced.

### Embodiment 3

Referring to FIG. 3, the display panel according to another preferred embodiment of the present invention comprises: a substrate 1; a thin film transistor unit disposed on the substrate 1, wherein the thin film transistor unit comprises: a gate electrode 21, a semiconductor layer 22, an insulating layer 26, and a buffer layer 27, wherein the semiconductor layer 22 includes a carrier channel region 221, and the gate electrode 21 is disposed above the semiconductor layer 22 and corresponding to the carrier channel region 221; a first metal oxide layer 32 disposed above the semiconductor layer 22 and at least covered the carrier channel region 221; and an isolation layer 31 containing silicon oxide (SiOx) or aluminum oxide (Al₂O₃) disposed between the semiconductor layer 22 and the first metal oxide layer 32; wherein the light transmittance of light with wavelength range from 210 nm to 350 nm through the first metal oxide layer 32 is under or equal to 50%.

In the present embodiment, the thin film transistor unit further comprises a source electrode 23 and a drain electrode 24. The source electrode 23 and the drain electrode 24 are disposed above the semiconductor layer 22. The first metal oxide layer 32 is disposed between the source electrode 23 and the drain electrode 24. The second metal oxide layer 33 may be disposed over the first metal oxide layer 32, the source electrode 23, and the drain electrode 24. The second metal oxide layer 33 may cover the source electrode 23 and the drain electrode 24. Depending on different requirements, the sidewall of the semiconductor layer 22 may be coated by the second metal oxide layer 33. A better UV light shielding effect is obtained.

The present embodiment is substantially the same as Embodiment 1 except for the configuration described above. Thus, the composition, thickness, area, and characteristics of each layer in Embodiment 1 are also applicable to the counterparts herein.

Therefore, in the present embodiment, the incident light from the external environment (as indicated by the arrow) in the wavelength range from 220 nm to 350 nm (for example, the ultraviolet light or blue light irradiation during the manufacturing process or from the external environment) may be absorbed by the first metal oxide layer 32 and the second metal oxide layer 33. Thereby, the impact of these lights on the semiconductor layer 22 is reduced.

While the invention has been shown and described in reference to certain exemplary examples thereof, it will be understood by those skilled in the art that various changes in the forms and details may be made therein without departing from the scope of the invention as defined by the appended claims.

What is claimed is:

1. A display panel, comprising:
a substrate;
a thin film transistor unit disposed on the substrate, wherein the thin film transistor unit comprises a gate electrode and a semiconductor layer, wherein the semiconductor layer comprises a carrier channel region, and the gate electrode is disposed corresponding to the carrier channel region;
a first metal oxide layer disposed on the semiconductor layer and covered the carrier channel region; and
an isolation layer containing silicon oxide (SiOx) or aluminum oxide (Al₂O₃) disposed between the semiconductor layer and the first metal oxide layer;
wherein the light transmittance of light with wavelength range from 210 nm to 350 nm through the first metal oxide layer is under or equal to 50%.

2. The display panel of claim 1, wherein the isolation layer has an area greater than or equal to the area of the first metal oxide layer.

3. The display panel of claim 1, wherein the first metal oxide layer is made of titanium oxide (TiOx), molybdenum oxide (MoOx), zinc oxide (ZnOx), indium oxide (InOx) , tungsten oxide (WOx), magnesium oxide (MgOx), calcium oxide (CaOx), Stannic oxide (SnOx), gallium oxide (GaOx), indium gallium zinc oxide (IGZO), or aluminum oxide (AlOx).

4. The display panel of claim 1, wherein the first metal oxide layer has a thickness of 30 nm to 100 nm.

5. The display panel of claim 1, wherein the isolation layer has a thickness of 5 nm to 20 nm.

6. The display panel of claim 1, wherein the thin film transistor unit is a top gate thin film transistor unit or a bottom gate thin film transistor unit.

7. The display panel of claim 1, wherein the thin film transistor unit further comprises a source electrode and a drain electrode, wherein the source electrode and the drain electrode are disposed above the semiconductor layer, and the first metal oxide layer is disposed between the semiconductor layer and both of the source electrode and the drain electrode.

8. The display panel of claim 7, further comprising a second metal oxide layer disposed above and covers the source electrode and the drain electrode.

9. The display panel of claim 1, wherein the thin film transistor unit further comprises a source electrode and a drain electrode, wherein the first metal oxide layer is disposed above and covers the source electrode and the drain electrode.

10. The display panel of claim 1, wherein the first metal oxide layer is coated on a sidewall of the semiconductor layer.

11. The display panel of claim 1, wherein the semiconductor layer is made of metal oxide semiconductors.

12. The display panel of claim 11, wherein the semiconductor layer is made of indium gallium zinc oxide (IGZO) or indium tin zinc oxide (ITZO).
